(19) United States
(12) Patent Application Publication
(10) Pub. No.: US 2025/0283426 A1
(43) Pub. Date: Sep. 11, 2025

(54) WATER PUMP DIAGNOSIS DEVICE

(71) Applicant: HONDA MOTOR CO., LTD., Tokyo (JP)

(72) Inventor: Kentaro SAKASHITA, Saitama (JP)

(21) Appl. No.: 19/052,370

(22) Filed: Feb. 13, 2025

(30) Foreign Application Priority Data
Mar. 6, 2024 (JP) 2024-034273

(51) Int. Cl. F01P 5/14; F04B 51/00; H05K 7/20

(52) U.S. Cl. CPC F01P 5/14; F01P 2025/46; F04B 51/00; H05K 7/2089

(57) ABSTRACT

A water pump diagnosis device diagnoses a water pump that circulates a coolant that cools a cooling target. The water pump diagnosis device includes a temperature sensor and a diagnosis unit. The temperature sensor measures a temperature of a power semiconductor, which is a part of the cooling target. The diagnosis unit determines whether the water pump has failed based on a comparison between a temperature rise rate of the power semiconductor based on a temperature measured by the temperature sensor and a preset reference temperature rise rate.

This application is based on and claims the benefit of priority from Japanese Patent Application No. 2024-034273, filed on 6 Mar. 2024, the content of which is incorporated herein by reference.

### BACKGROUND OF THE INVENTION

### Field of the Invention

The present invention relates to a water pump diagnosis device for detecting a failure of a water pump.

### Related Art

Some vehicles include a water pump that circulates a coolant for cooling a cooling target such as a vehicle control unit.

Patent Document 1: Japanese Unexamined Patent Application, Publication No. 2017-115680

### SUMMARY OF THE INVENTION

When the water pump fails and the flow rate of the coolant decreases, various problems may occur due to a rise in the temperature of the cooling target. Therefore, it is preferable for it to be possible to quickly diagnose whether or not the water pump has failed.

As a technique of detecting a failure of a water pump, for example, there is a technique of diagnosing whether or not the water pump has a failure based on the rotation speed of the water pump. However, with such a method, it is not possible to diagnose whether or not a water pump to which the rotation speed sensor is not attached has failed.

The present invention has been made in view of the above circumstances, and it is an object of the present invention to diagnose whether or not a water pump has failed without being based on the rotation speed of the water pump.

The inventors of the present invention have found that it is possible to detect the failure of a water pump without being based on the rotation speed of the water pump, when focusing on a temperature rise of a power semiconductor as a part of a cooling target, thereby arriving at the present invention. The present invention provides the following water pump diagnostic devices (1) to (5).
(1) A water pump diagnosis device for diagnosing a water pump that circulates a coolant for cooling a cooling target, the water pump diagnosis device including:
   a temperature sensor that measures a temperature of a power semiconductor, which is a part of the cooling target; and a diagnoser that determines whether the water pump has failed based on a comparison between a temperature rise rate of the power semiconductor based on a temperature measured by the temperature sensor and a preset reference temperature rise rate.

According to the present configuration, it is possible to estimate the flow rate of the coolant from the comparison between the temperature rise rate of the power semiconductor and the reference temperature rise rate. That is, it is possible to estimate that the flow rate of the coolant is smaller as the temperature rise rate of the power semiconductor is higher than the reference temperature rise rate. Therefore, it is possible to diagnose whether or not the water pump has failed without being based on the rotation speed of the water pump.
(2) In the water pump diagnosis device according to (1), the cooling target, the water pump, and the water pump diagnosis device are installed in a vehicle,
   the cooling target includes a power module for driving the vehicle, and
   the power semiconductor is a part of the power module.

According to the present configuration, in the vehicle, it is possible to obtain an advantageous effect of diagnosing whether or not the water pump has failed without being based on the rotation speed of the water pump.
(3) The water pump diagnosis device as described in (1) or (2) further includes an alarm that warns that the water pump has failed on a condition that the diagnoser determines that the water pump has failed.

According to the present configuration, it is possible for the driver to quickly recognize the failure when the water pump fails.
(4) In the water pump diagnosis device as described in any one of (1) to (3), the diagnoser
   determines that the water pump has failed on a condition that a rise rate difference defined as a value obtained by subtracting the reference temperature rise rate from the temperature rise rate of the power semiconductor based on a temperature measured by the temperature sensor is larger than a predetermined failure determination value, and
   determines that the water pump has stopped on a condition that the rise rate difference is larger than a stop determination value which is larger than the failure determination value.

According to the present configuration, it is possible to diagnose in detail the state of the water pump.
(5) The water pump diagnosis device as described in (4), further includes an alarm that warns that the water pump has failed on a condition that the diagnoser determines that the water pump has failed, and warns that the water pump has stopped on a condition that the diagnoser determines that the water pump has stopped.

According to the present configuration, it is possible for the driver to recognize in detail the state of the water pump.

As described above, according to the configuration (1), it is possible to diagnose whether or not the water pump has failed without being based on the rotation speed of the water pump. Further, according to the configurations (2) to (4) citing (1), it is possible to obtain the respective additional advantageous effects.

### BRIEF DESCRIPTION OF THE DRAWINGS

FIG. 1 is a configuration diagram showing a water pump diagnostic device and its periphery according to a first embodiment;

FIG. 2 is a plan view showing an example of a power semiconductor and its periphery;

FIG. 3 is a front view showing an example of a power semiconductor and its periphery;

FIG. 4 is a graph showing a relationship between a working time and a temperature of a power semiconductor for every flow rate of a coolant; and

FIG. 5 is a flowchart showing a flow of diagnosis by the water pump diagnosis device.

### DETAILED DESCRIPTION OF THE INVENTION

Hereinafter, embodiments of the present invention will be described with reference to the drawings. However, the present invention is not limited to the following embodiments, and can be appropriately modified and implemented within a range not departing from the gist of the present invention.

### First Embodiment

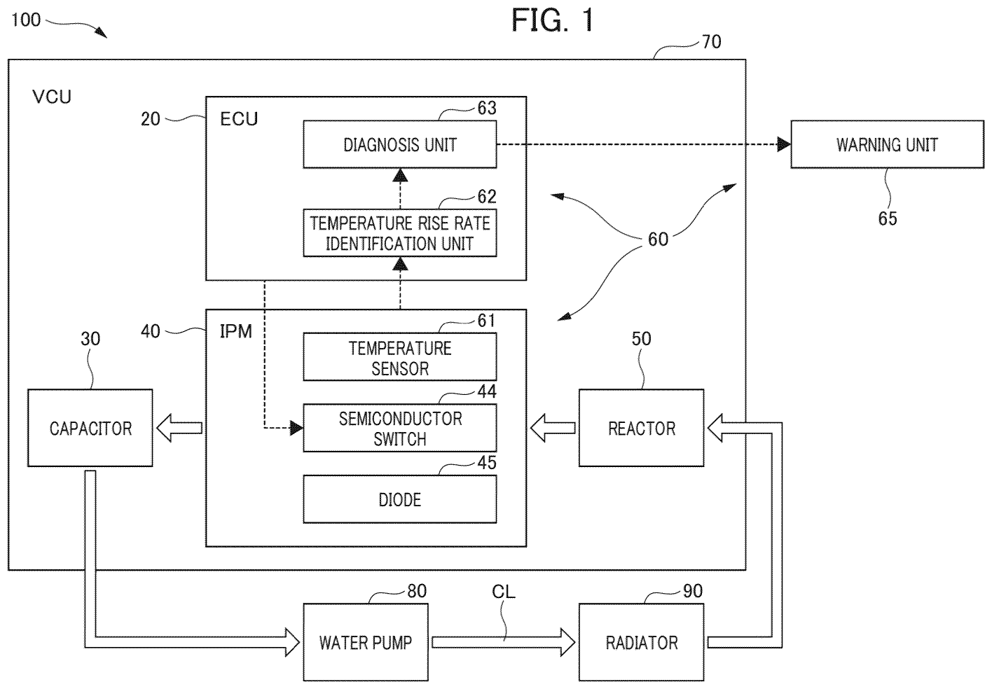

As shown in FIG. 1, a water pump diagnosis device 60 of the present embodiment is installed in a vehicle 100. The vehicle 100 includes a VCU 70, a water pump 80, and a radiator 90. The VCU is an abbreviation for “Vehicle Control Unit”.

The VCU 70 includes an ECU 20, a capacitor 30, an IPM 40, and a reactor 50. Note that “ECU” is an abbreviation for “Electronic Control Unit”. Further, “IPM” is an abbreviation for “Intelligent Power Module”. That is, the “IPM” is a power module for driving the vehicle.

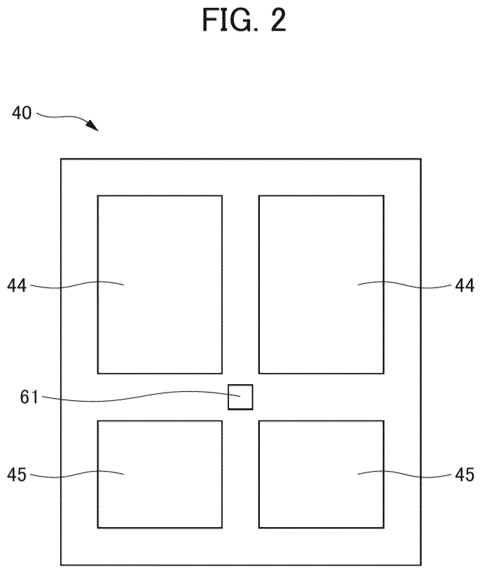

The IPM 40 includes an input-side circuit for inputting power to the reactor 50 and an output-side circuit for outputting power from the reactor 50. Therefore, as shown in FIG. 2, the IPM 40 includes a plurality of power semiconductors such as a semiconductor switch 44 and a diode 45. The capacitor 30 shown in FIG. 1 is, for example, a smoothing capacitor in the input-side circuit or a smoothing capacitor in the output-side circuit.

The ECU 20 shown in FIG. 1 controls the IPM 40 by controlling the semiconductor switches 44 shown in FIG. 2.

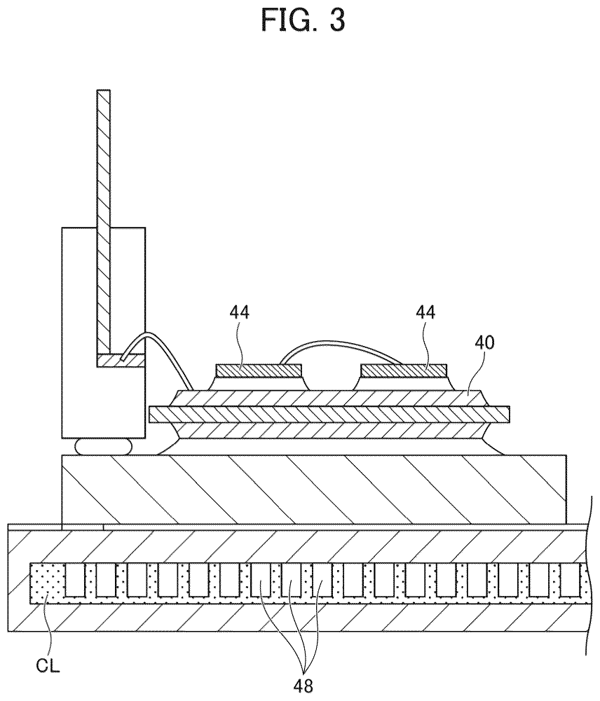

The water pump 80 shown in FIG. 1 circulates a coolant CL for cooling the condenser 30, the IPM 40, and the reactor 50 in the vehicle 100. Hereinafter, the capacitor 30, the IPM 40, and the reactor 50 will be referred to as “cooling targets 30, 40, 50”. The water pump 80 cools the cooling targets 30, 40, and 50 by circulating the coolant CL between the cooling targets 30, 40, and 50 and the radiator 90. Specifically, for example, as illustrated in FIG. 3, the coolant CL passes between fins 48 for promoting cooling below the cooling targets 30, 40, and 50.

As shown in FIG. 1, the water pump diagnosis device 60 includes a temperature sensor 61, a temperature rise rate identification unit 62, a diagnosis unit 63, and a warning unit 65. The temperature sensor 61 is installed in the IPM 40. Each of the temperature rise rate identification unit 62 and the diagnosis unit 63 is configured as a part of the ECU 20. The warning unit 65 is provided in front of or in the vicinity of the driver's seat in the vehicle 100.

The temperature sensor 61 measures the temperature Ta of the semiconductor switch 44. The temperature rise rate identification unit 62 identifies the temperature rise rate Va of the semiconductor switch 44 from the rise in the temperature Ta of the semiconductor switch 44 relative to the operation time t of the semiconductor switch 44.

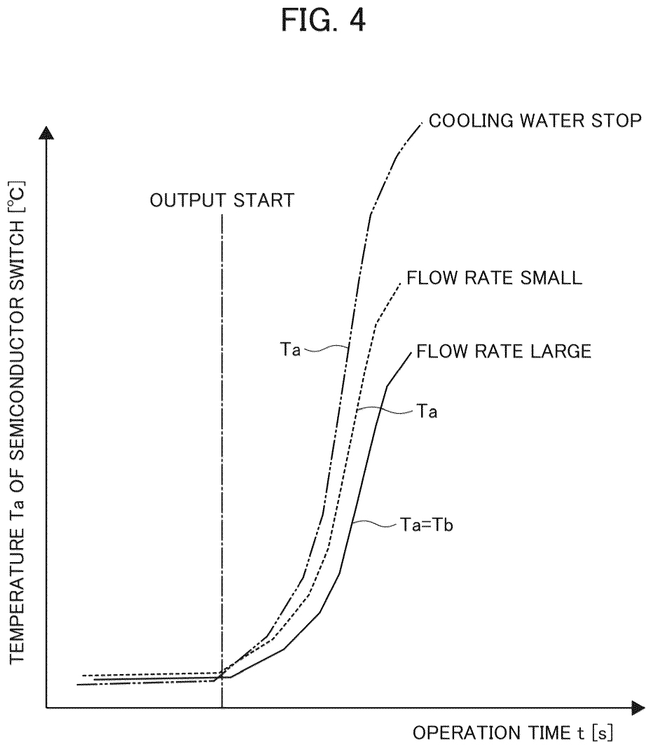

The diagnosis unit 63 stores a preset reference temperature rise rate Vb. Specifically, the diagnosis unit 63 maps and stores the reference temperature rise rate Vb for every situation. As shown in FIG. 4, the reference temperature rise rate Vb is a rise rate of the temperature Ta=Tb of the semiconductor switch 44 when the water pump 80 is normal, that is, when the flow rate of the coolant CL is high. The reference temperature rise rate Vb may be, for example, a value obtained by experiment in advance or a value obtained by simulation in advance.

The diagnosis unit 63 shown in FIG. 1 diagnoses the water pump 80 based on a comparison between the temperature rise rate Va of the semiconductor switch 44 identified by the temperature rise rate identification unit 62 and the reference temperature rise rate Vb. Hereinafter, a value (Va-Vb) obtained by subtracting the reference temperature rise rate Vb from the temperature rise rate Va of the semiconductor switch 44 is referred to as a “rise rate difference ΔV”. The two predetermined threshold values are referred to as a “failure determination value th1” and a “stop determination value th2” in order from smaller.

When the rise rate difference ΔV is less than the failure determination value th1, the diagnosis unit 63 determines that the water pump 80 is normal. On the other hand, when the rise rate difference ΔV exceeds the failure determination value th1, the diagnosis unit 63 determines that the water pump 80 has failed. Further, when the rise rate difference ΔV exceeds the stop determination value th2, the diagnosis unit 63 determines that the water pump 80 has stopped.

The warning unit 65 warns the driver of the vehicle 100 that the water pump 80 has failed on condition that the diagnosis unit 63 has determined that the water pump 80 has failed. Specifically, for example, a warning that the flow rate of the coolant CL is decreasing is issued. The warning unit 65 warns the driver of the vehicle 100 that the water pump 80 has stopped on the condition that the diagnosis unit 63 determines that the water pump 80 has stopped. These warnings may be, for example, visually appealing such as a warning screen display or a warning lamp, may be audibly appealing such as a warning sound or a warning announcement, or may be both.

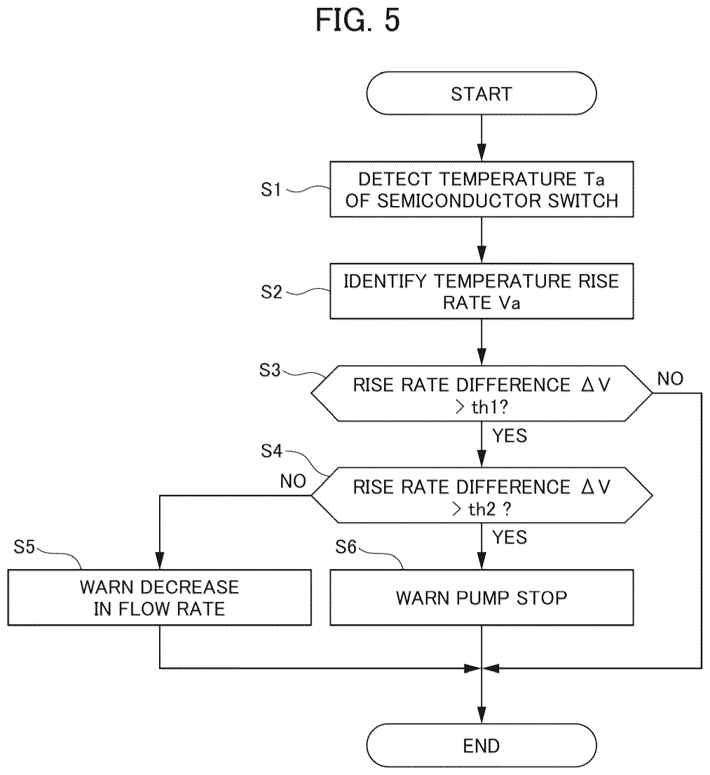

Next, the flow of diagnosis by the water pump diagnosis device 60 described above will be described with reference to FIG. 5. In the following description, the “S” added before a numeral is an abbreviation for “step”.

First, in S1, the temperature sensor 61 detects the temperature Ta of the semiconductor switch 44. Next, in S2, the temperature rise rate identification unit 62 identifies the temperature rise rate Va of the semiconductor switch 44.

Next, in S3, the diagnosis unit 63 determines whether or not the rise rate difference ΔV has exceeded the failure determination value th1. When the diagnosis unit 63 makes a negative determination, that is, when the rise rate difference ΔV is less than the failure determination value th1, it is determined that the water pump 80 is normal, and the processing flow ends. On the other hand, when the diagnosis unit 63 makes an affirmative determination in S3, that is, when the rise rate difference ΔV has exceeded the failure determination value th1, it is determined that the water pump 80 has failed, and the processing advances to S4.

In S4, the diagnosis unit 63 determines whether or not the rise rate difference ΔV has exceeded the stop determination value th2. When the diagnosis unit 63 makes a negative determination, that is, when the rise rate difference ΔV is less than the stop determination value th2, it is determined that the water pump 80 is not stopped, and the processing advances to S5. In S5, the warning unit 65 warns that the flow rate of the coolant is decreasing.

On the other hand, when the diagnosis unit 63 makes an affirmative determination in S5 described above, that is, when the rise rate difference ΔV has exceeded the stop determination value th2, it is determined that the water pump 80 has stopped, and the processing advances to S6. In S6, the warning unit 65 warns that the water pump 80 has stopped.

The configuration and advantageous effects of the present embodiment will be summarized below.

The temperature sensor 61 shown in FIG. 1 measures the temperature Ta of the semiconductor switch 44, which is a part of the cooling targets 30, 40, and 50. The diagnosis unit 63 determines whether or not the water pump 80 has failed based on a comparison between the temperature rise rate Va of the semiconductor switch 44 based on the temperature Ta measured by the temperature sensor 61 and a preset reference temperature rise rate Vb. That is, it can be estimated that the flow rate of the coolant CL is smaller as the temperature rise rate Va of the semiconductor switch 44 is higher than the reference temperature rise rate Vb. Therefore, it is possible to diagnose whether or not the water pump 80 has failed without being based on the rotation speed of the water pump 80.

The cooling targets 30, 40, 50, the water pump 80, and the water pump diagnosis device 60 are installed in the vehicle 100. The cooling targets 30, 40, and 50 include an IPM 40 for driving the vehicle 100. The semiconductor switch 44 for measuring the temperature is a part of the IPM 40. Therefore, in the vehicle 100, it is possible to obtain the above advantageous effect, that is, an advantageous effect of possible to diagnose whether or not the water pump 80 has failed without being based on the rotation speed of the water pump 80.

The warning unit 65 warns the driver of the vehicle 100 that the water pump 80 has failed on condition that the diagnosis unit 63 has determined that the water pump 80 has failed. Therefore, it is possible for the driver to quickly recognize that the water pump 80 has failed.

The diagnosis unit 63 determines that the water pump 80 has failed on the condition that the rise rate difference ΔV is larger than the failure determination value th1. In addition, the diagnosis unit 63 determines that the water pump 80 has stopped on the condition that the rise rate difference ΔV is larger than the stop determination value th2. Therefore, it is possible to diagnose in detail the failure state of the water pump.

The warning unit 65 warns the driver that the water pump 80 has failed on condition that the diagnosis unit 63 determines that the water pump 80 has failed. Further, the warning unit 65 warns the driver that the water pump 80 has stopped on the condition that the diagnosis unit 63 determines that the water pump 80 has stopped. Therefore, it is possible for the driver to recognize in detail the failure state of the water pump 80.

### Other Embodiments

The embodiment described above can be modified as follows, for example.

When the rise rate difference ΔV is larger than the failure determination value th1, the diagnosis unit 63 may only determine that the water pump 80 has failed, and may not determine whether the water pump 80 has stopped. The warning unit 65 may only warn the driver that the water pump 80 has failed on condition that the diagnosis unit 63 determines that the water pump 80 has failed.

In a case in which the diagnosis unit 63 determines that the water pump 80 has failed or has stopped, a predetermined fail-safe action may be performed instead of or in addition to the warning by the warning unit 65.

Instead of measuring the temperature of the semiconductor switch 44 shown in FIG. 2, the temperature of the diode 45 may be measured by the temperature sensor 61.

### EXPLANATION OF REFERENCE NUMERALS

44 Semiconductor Switch (Power Semiconductor)
45 Diode (Power Semiconductor)
60 Water Pump Diagnosis Device
61 Temperature Sensor
63 Diagnosis Unit
65 Warning Unit
80 Water Pump
100 Vehicle
Th1 Failure Determination Value
Th2 Stop Determination Value
Va Temperature Rise Rate of Semiconductor Switch (Temperature
Rise Rate of Power Semiconductor)
Vb Reference Temperature Rise Rate
ΔV Rise Rate Difference

What is claimed is:

1. A water pump diagnosis device for diagnosing a water pump that circulates a coolant for cooling a cooling target, the water pump diagnosis device comprising:
a temperature sensor that measures a temperature of a power semiconductor, which is a part of the cooling target; and
a diagnoser that determines whether the water pump has failed based on a comparison between a temperature rise rate of the power semiconductor based on a temperature measured by the temperature sensor and a preset reference temperature rise rate.

2. The water pump diagnosis device according to claim 1, wherein
the cooling target, the water pump, and the water pump diagnosis device are installed in a vehicle,
the cooling target includes a power module for driving the vehicle, and
the power semiconductor is a part of the power module.

3. The water pump diagnosis device according to claim 1, further comprising an alarm that warns that the water pump has failed on a condition that the diagnoser determines that the water pump has failed.

4. The water pump diagnosis device according to claim 1, wherein the diagnoser
determines that the water pump has failed on a condition that a rise rate difference defined as a value obtained by subtracting the reference temperature rise rate from the temperature rise rate of the power semiconductor based on a temperature measured by the temperature sensor is larger than a predetermined failure determination value, and
determines that the water pump has stopped on a condition that the rise rate difference is larger than a stop determination value which is larger than the failure determination value.

5. The water pump diagnosis device according to claim 4, further comprising an alarm that warns that the water pump has failed on a condition that the diagnoser determines that the water pump has failed, and warns that the water pump has stopped on a condition that the diagnoser determines that the water pump has stopped.
